(19) United States
(12) Patent Application Publication
(10) Pub. No.: US 2025/0167051 A1
(43) Pub. Date: May 22, 2025

(54) ELECTRONIC DEVICE FOR PREDICTING CHARACTERISTIC OF SEMICONDUCTOR DEVICE AND OPERATING METHOD OF ELECTRONIC DEVICE

(71) Applicant: SAMSUNG ELECTRONICS CO., LTD., Suwon-si (KR)

(72) Inventors: Seonghyeon Hwang, Daejeon (KR); Euijong Whang, Daejeon (KR); Hyunsoo Kwak, Suwon-si (KR); Sung Yoon Ryu, Suwon-si (KR); Sooseok Lee, Suwon-si (KR); Younghoon Sohn, Suwon-si (KR)

(73) Assignees: SAMSUNG ELECTRONICS CO., LTD., Suwon-si (KR); KOREA ADVANCED INSTITUTE OF SCIENCE AND TECHNOLOGY, Daejeon (KR)

(21) Appl. No.: 18/765,917

(22) Filed: Jul. 8, 2024

(30) Foreign Application Priority Data
Nov. 22, 2023 (KR) 10-2023-0163647

(51) Int. Cl. H01L 21/66; H01J 37/28

(52) U.S. Cl. CPC H01L 22/12; H01J 37/28; H01L 22/20; H01J 2237/2802

(57) ABSTRACT

A method of operating an electronic device includes selecting, by at least one processor, M first sample-label pairs (M being a positive integer); obtaining, by the at least one processor, M K-values; selecting, by the at least one processor, M second sample-label pairs respectively corresponding to the M first sample-label pairs based on the M K-values, generating, by the at least one processor, M third sample-label pairs based on the M first sample-label pairs and the M second sample-label pairs, and training, by the at least one processor, a regression analysis module based on the M third sample-label pairs, and the regression analysis module is trained to predict labels, which are associated with the semiconductor device, from the M third sample-label pairs.

### CROSS-REFERENCE TO RELATED APPLICATION

This application claims priority under 35 U.S.C. § 119 to Korean Patent Application No. 10-2023-0163647 filed on Nov. 22, 2023, in the Korean Intellectual Property Office, the disclosure of which is herein incorporated by reference in its entirety.

### BACKGROUND

One or more example embodiments of the present disclosure described herein relate to an electronic device, and more particularly, relate to an electronic device for predicting a characteristic of a semiconductor device by using a prediction model with improved consistency and an operating method of the electronic device.

After a semiconductor device is manufactured, features of the semiconductor device may be measured. Physical features and/or characteristics of the semiconductor device may be predicted by using a result of measuring the features of the semiconductor device. For example, a machine learning module configured to predict physical characteristics of the semiconductor device from a result of measuring the features of the semiconductor device may be implemented.

For learning (or training) of a machine learning module, a large amount of data may be required. As the required accuracy of the machine learning module increases, the amount of data necessary for learning or training the machine learning module may increase. When the amount of data necessary for learning or training is insufficient, the consistency of the machine learning module may decrease.

### SUMMARY

Example embodiments of the present disclosure provide an electronic device for predicting a characteristic of a semiconductor device by using a machine learning module, while increasing consistency of the machine learning module by generating data and a label appropriate for learning of the machine learning module, and an operating method of the electronic device.

According to an aspect of one or more example embodiments of the present disclosure, provided is a method of operating an electronic device which includes at least one processor, the method including: selecting, by the at least one processor, M (M being a positive integer) number of first sample-label pairs; obtaining, by the at least one processor, M number of K-values; selecting, by the at least one processor, M number of second sample-label pairs, respectively corresponding to the M number of first sample-label pairs, based on the M number of K-values; generating, by the at least one processor, M number of third sample-label pairs based on the M number of first sample-label pairs and the M number of second sample-label pairs; and training, by the at least one processor, a regression analysis module based on the M number of third sample-label pairs, wherein each of the M number of first sample-label pairs, the M number of second sample-label pairs, and the M number of third sample-label pairs includes data measured from a semiconductor device as a sample and a label associated with the semiconductor device, and wherein the regression analysis module is trained to predict labels, which are associated with the semiconductor device, from the M number of third sample-label pairs.

According to an aspect of one or more example embodiments of the present disclosure, provided is an operating method of an electronic device which includes at least one processor, the method including: receiving, by the at least one processor, a sample measured from a semiconductor device; and predicting from the sample, by the at least one processor, a label associated with the semiconductor device by using a regression analysis module that is based on a machine learning, wherein learning of the regression analysis module is performed based on mix-up data augmentation, wherein the mix-up data augmentation includes: selecting second sample-label pairs from first sample-label pairs based on K-values; and generating third sample-label pairs by mixing up the first sample-label pairs and the second sample-label pairs, and wherein the K-values include distance information corresponding to each of labels of the first sample-label pairs.

According to an aspect of one or more example embodiments, provided is an electronic device for predicting a characteristic of a semiconductor device, the electronic device including: at least one processor; and at least one memory configured to store M (M being a positive integer) number of first sample-label pairs, wherein the at least one processor is configured to: obtain M number of K-values; select M number of second sample-label pairs, respectively corresponding to the number of M first sample-label pairs, based on the M number of K-values; generate M number of third sample-label pairs based on the M number of first sample-label pairs and the M number of second sample-label pairs; and train a regression analysis module based on the M number of third sample-label pairs, wherein the regression analysis module is trained to predict labels, which are associated with the semiconductor device, from the M number of third sample-label pairs, and wherein the K-values include distance information corresponding to each of labels of the first sample-label pairs.

### BRIEF DESCRIPTION OF DRAWINGS

The above and other objects and features of the present disclosure will become apparent by describing in detail some example embodiments thereof with reference to the accompanying drawings.

FIG. 1 illustrates a semiconductor manufacturing system according to one or more example embodiments of the present disclosure.

FIG. 2 is a block diagram illustrating an electronic device according to one or more example embodiments of the present disclosure.

FIG. 3 illustrates an example of obtaining a sample-label pair for learning of a learning device according to one or more example embodiments of the present disclosure.

FIG. 4 illustrates an example of sample-label pairs stored in a database according to one or more example embodiments of the present disclosure.

FIG. 5 is a diagram illustrating an example of a sample according to one or more example embodiments of the present disclosure.

FIG. 6 illustrates an example of a learning module according to one or more example embodiments of the present disclosure.

FIG. 7 illustrates a method of operating a learning module according to one or more example embodiments of the present disclosure.

FIG. 8 illustrates a method of performing mix-up data augmentation in a learning module according to one or more example embodiments.

FIG. 9 illustrates an example of a process in which a learning module selects target labels of mix-up data augmentation according to one or more example embodiments.

FIG. 10 illustrates an example of a learning module according to one or more example embodiments.

FIG. 11 illustrates a method of operating a learning module according to one or more example embodiments of the present disclosure.

FIG. 12 illustrates an example in which a learning device is applied to a manufacture of semiconductor devices after learning of the learning device is completed, according to one or more example embodiments.

FIG. 13 illustrates an example in which a learning device is applied to a manufacture of semiconductor devices after learning of the learning device is completed, according to one or more example embodiments.

FIG. 14 illustrates a learning performance of a learning module according to one or more example embodiments of the present disclosure and a learning performance of a comparative example.

### DETAILED DESCRIPTION

Below, example embodiments of the present disclosure will be described in detail and clearly to such an extent that an ordinary one in the art easily carries out the present disclosure.

Hereinafter, the term “label” is used. The “label” may include a unit of data and “labels” may include two or more units of data. The unit of data of the label may be interchangeably referred to as “label data”.

Hereinafter, the term “sample” is used. The “sample” may include a unit of data and “samples” may include two or more units of data. The unit of data of the sample may be interchangeably referred to as “sample data”.

Hereinafter, the term “sample-label pair” is used. The “sample-label pair” may include one sample and one label, which corresponds to each other. “Sample-label pairs” may include two or more samples and two or more labels, which respectively correspond to each other.

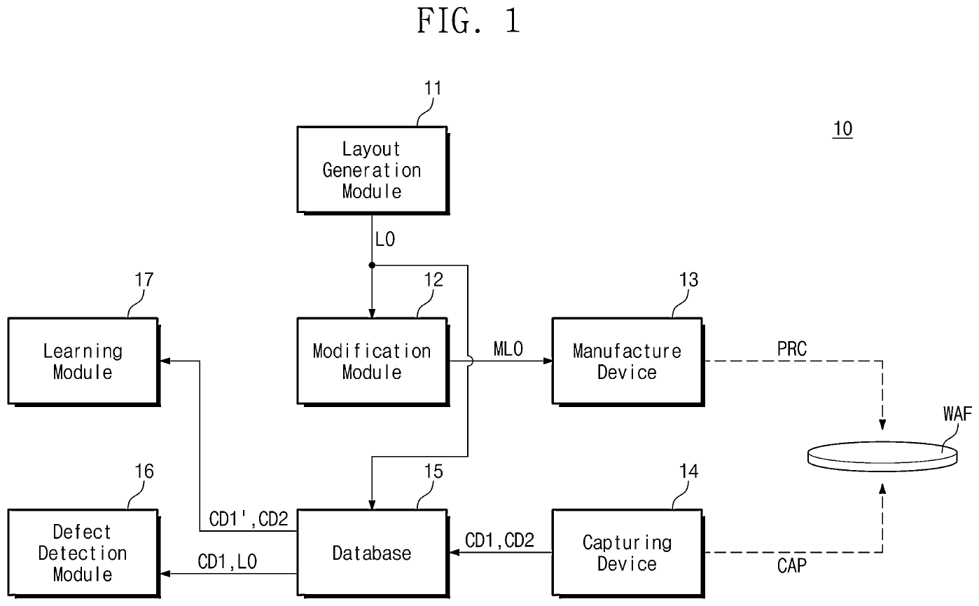

FIG. 1 illustrates a semiconductor manufacturing system 10 according to one or more example embodiments of the present disclosure. Referring to FIG. 1, the semiconductor manufacturing system 10 may include a layout generation module 11, a modification module 12, a manufacture device 13, a capturing device 14, a database 15, a defect detection module 16, and a learning module 17. The semiconductor manufacturing system 10 may manufacture a semiconductor device by using a wafer WAF.

The layout generation module 11 may generate a layout image LO. For example, the layout generation module 11 may generate or receive circuit-based design information. The layout generation module 11 may generate the layout image LO by placing, on a layout, standard cells based on the design information. Alternatively, after the layout generation module 11 places, on the layout, the standard cells, the layout generation module 11 may generate the layout image LO by modifying the standard cells or placing specialization cells, which are not included in the standard cells, in the layout under control of the user. For example, the layout image LO which the layout generation module 11 generates may be a new layout image LO for a manufacture of new semiconductor devices.

The modification module 12 may generate a modified layout image MLO from the layout image LO. The modification module 12 may generate the modified layout image MLO from the layout image LO based on various factors that may be caused in the process of manufacturing semiconductor devices, for example, the modification module 12 may generate the modified layout image MLO based at least on a process proximity correction (PPC) and an optical proximity correction (OPC).

For example, the optical proximity correction may be performed to correct a distortion caused in a photoresist pattern due to various factors, which may include a feature of a light source, a feature of a photoresist, positional relationships between the light source and patterns formed in the photoresist, etc., in the process of generating a photomask for the manufacture of semiconductor devices. The process proximity correction may be used to correct a distortion caused during a process (e.g., an etching process) due to various factors that may include a feature of a material that is used in performing the process, a feature of a material to which the process is applied, a features of a photoresist pattern, etc.

For example, the modification module 12 may be a machine learning module which is trained to generate the modified layout image MLO from the layout image LO. The modification module 12 may be implemented based on one of various neural networks such as, for example but not limited to, a DNN (Deep Neural Network), a CNN (Convolution Neural Network), a RNN (Recurrent Neural Network), and an FFNN (FeedForward Neural Network).

The manufacture device 13 may receive the modified layout image MLO from the modification module 12. The manufacture device 13 may apply processes PRC to the wafer WAF based on the modified layout image MLO. For example, the processes PRC may include an etching process, a deposition process, a growth process, a planarization process, etc. As the processes PRC are applied to the wafer WAF, semiconductor devices may be formed in the wafer WAF.

The capturing device 14 may capture features of the semiconductor devices formed in the wafer WAF to generate first capture data CD1 and second capture data CD2. For example, the capturing device 14 may include at least one of a scanning electron microscope (SEM) or a transmission electron microscope (TEM). The capturing device 14 may output image data captured (e.g., photographed) from the semiconductor devices formed in the wafer WAF as the first capture data CD1.

For example, the capturing device 14 may include an ellipsometer. The capturing device 14 may output spectrum data measured (or obtained) from the semiconductor devices formed in the wafer WAF as the second capture data CD2.

The database 15 may receive the layout image LO from the layout generation module 11 and may receive the first capture data CD1 and the second capture data CD2 of the semiconductor devices manufactured based on the layout image LO from the capturing device 14. The database 15 may store and manage the layout image LO and the first capture data CD1, which correspond to each other, in pairs.

The database 15 may store and manage measurement data CD1′, measured from the first capture data CD1, and the second capture data CD2, which correspond to each other, in pairs. For example, the measurement data CD1′ measured from the first capture data CD1 may include physical information of an element(s) of a semiconductor device. The measurement data CD1′ may include a length of an element(s) of a semiconductor device, a distance between elements of a semiconductor device, or a thickness of an element(s) of a semiconductor device.

In one or more example embodiments, the database 15 may measure the measurement data CD1′ from the first capture data CD1 by using an embedded processor of the database 15. As another example, the database 15 may provide the first capture data CD1 to an external processor and may receive the measurement data CD1′ corresponding to the first capture data CD1 from the external processor.

The defect detection module 16 may receive the layout image LO and the first capture data CD1, which correspond to each other, from the database 15. The defect detection module 16 may detect a defect of the semiconductor devices by comparing the layout image LO and the first capture data CD1. That is, the defect detection module 16 may detect the defect of the semiconductor devices by comparing a pre-image (e.g., the layout image LO) and a post-image (e.g., the first capture data CD1) of the semiconductor devices.

The learning module 17 may receive the second capture data CD2 and the measurement data CD1′ from the database 15. For example, the learning module 17 may identify the second capture data CD2 that may be a spectrum measured by the ellipsometer as a sample. The learning module 17 may identify physical information of a semiconductor device measured by using the SEM and/or TEM as a label.

The learning module 17 may manage sample-label pairs. Each of the sample-label pairs may include one sample and one label, which correspond to each other. The learning module 17 may perform machine learning based on the sample-label pairs. For example, the learning module 17 may be trained to predict (or infer) labels from samples.

The operation (or process) of generating the measurement data CD1′ from the first capture data CD1 may be referred to as “labeling” that assigns a label to the first capture data CD1. To perform the labeling with respect to all data for the learning of the learning module 17 may require a significant amount of time.

The learning module 17 according to one or more example embodiments of the present disclosure may receive sample-label pairs from the database 15. The learning module 17 may perform machine learning based on the received sample-label pairs. The learning module 17 may generate new sample-label pairs by performing mix-up data augmentation with respect to the received sample-label pairs. The learning module 17 may perform additional learning based on the newly generated sample-label pairs. That is, the learning module 17 may perform learning while reducing time required for labeling.

At the time of performing the mix-up data augmentation, the learning module 17 may perform the mix-up data augmentation with respect to sample-label pairs based on a distance between labels. The mix-up data augmentation between sample-label pairs in which a distance between labels is relatively distant (e.g., a threshold distance or greater) may be blocked by the learning module 17. Accordingly, an unsuitable new label may be prevented from being generated due to the mix-up data augmentation of labels distant from each other, and an unsuitable new sample may be prevented from being assigned to the unsuitable new label due to the mix-up data augmentation of samples corresponding to the labels distant from each other.

In one or more example embodiments, the layout generation module 11, the modification module 12, the defect detection module 16, and the learning module 17 may be implemented in the form of software executable by a processor, in the form of a processor designed to perform a relevant function, or in the form of a combination of hardware and software designed to perform a relevant function.

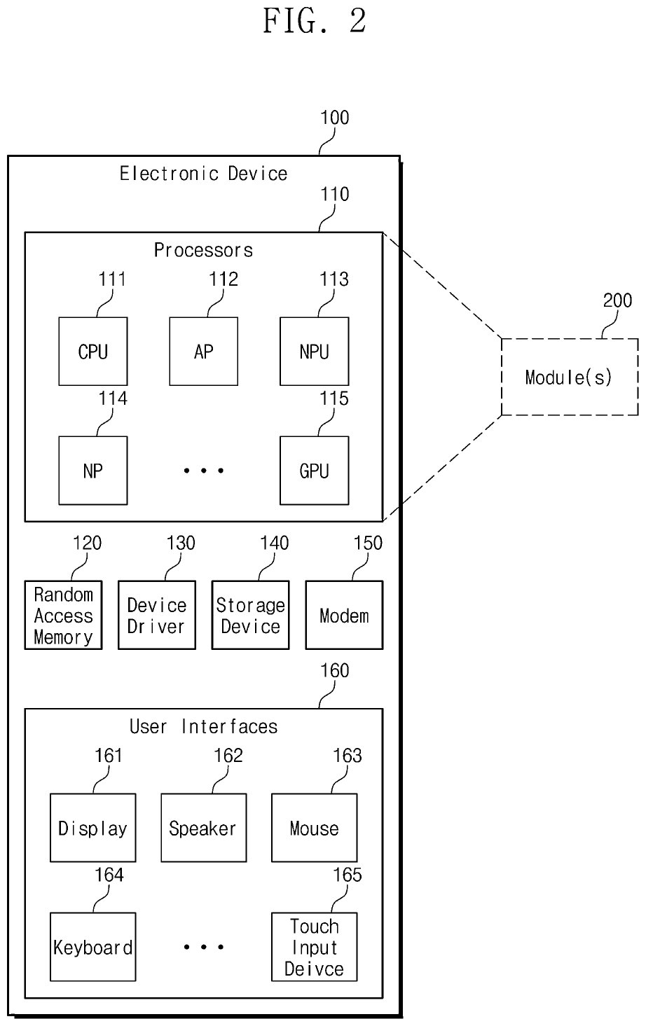

FIG. 2 is a block diagram illustrating an electronic device 100 according to one or more example embodiments of the present disclosure. Referring to FIG. 2, the electronic device 100 may include processors 110, a random access memory 120, a device driver 130, a storage device 140, a modem 150, and user interfaces 160.

The processors 110 may include, for example, at least one general-purpose processor such as a central processing unit (CPU) 111 or an application processor (AP) 112. Also, the processors 110 may further include at least one special-purpose processor such as a neural processing unit (NPU) 113, a neuromorphic processor (NP) 114, and/or a graphics processing unit (GPU) 115. The processors 110 may include two or more homogeneous processors.

At least one of the processors 110 may be used to train a module(s) 200 or to execute the trained module(s) 200. At least one of the processors 110 may train or execute the module(s) 200 based on various data or information. For example, the module(s) 200 may be implemented in the form of instructions (or codes) which are executed by at least one of the processors 110. In this case, the at least one processor may load the instructions (or codes) of the module(s) 200 to the random access memory 120.

For another example, at least one (or at least another) processor among the processors 110 may be manufactured to implement the module(s) 200. For example, the at least one processor may be a dedicated processor which is implemented in the form of hardware based on the module(s) 200 generated by the learning of the module(s) 200.

For another example, at least one (or at least another) processor among the processors 110 may be manufactured to implement various machine learning and/or deep learning modules. The at least one processor may implement the module(s) 200 by receiving information (e.g., instructions or codes) corresponding to the module(s) 200.

The random access memory 120 may be used as a working memory of the processors 110 and may be used as a main memory or a system memory of the electronic device 100. The random access memory 120 may include a volatile memory such as a dynamic random access memory or a static random access memory, or a nonvolatile memory such as a phase-change random access memory, a ferroelectric random access memory, a magnetic random access memory, and/or a resistive random access memory.

The device driver 130 may control peripheral devices based on a request of the processors 110, and the peripheral devices controlled by the device driver 130 may include the storage device 140, the modem 150, and the user interfaces 160. The storage device 140 may include a stationary storage device such as a hard disk drive and/or a solid state drive, and/or a removable storage device such as an external hard disk drive, an external solid state drive, and/or a removable memory card.

The modem 150 may provide remote communication with the external device. The modem 150 may perform wired and/or wireless communication with the external device. The modem 150 may communicate with the external device based on at least one of various communication schemes such as Ethernet, wireless-fidelity (Wi-Fi), long term evolution (LTE), and 5th generation (5G) mobile communication.

The user interfaces 160 may receive information from the user and may provide information to the user. The user interfaces 160 may include at least one user output interface such as a display 161 or a speaker 162, and at least one user input interface such as a mouse 163, a keyboard 164, and/or a touch input device 165.

The instructions (or codes) of the module(s) 200 may be received through the modem 150 and may be stored in the storage device 140. The instructions (or codes) of the module(s) 200 may be stored in a removable storage device, and the removable storage device may be connected to the electronic device 100. The instructions (or codes) of the module(s) 200 may be loaded to the random access memory 120 from the storage device 140 so as to be executed thereon.

In one or more example embodiments, the module(s) 200 may include at least one of the layout generation module 11, the modification module 12, the defect detection module 16, and the learning module 17 described with reference to FIG. 1. The layout generation module 11, the modification module 12, the defect detection module 16, and the learning module 17 may be implemented or executed in different electronic devices. At least two of the layout generation module 11, the modification module 12, the defect detection module 16, and the learning module 17 may be implemented or executed in one electronic device.

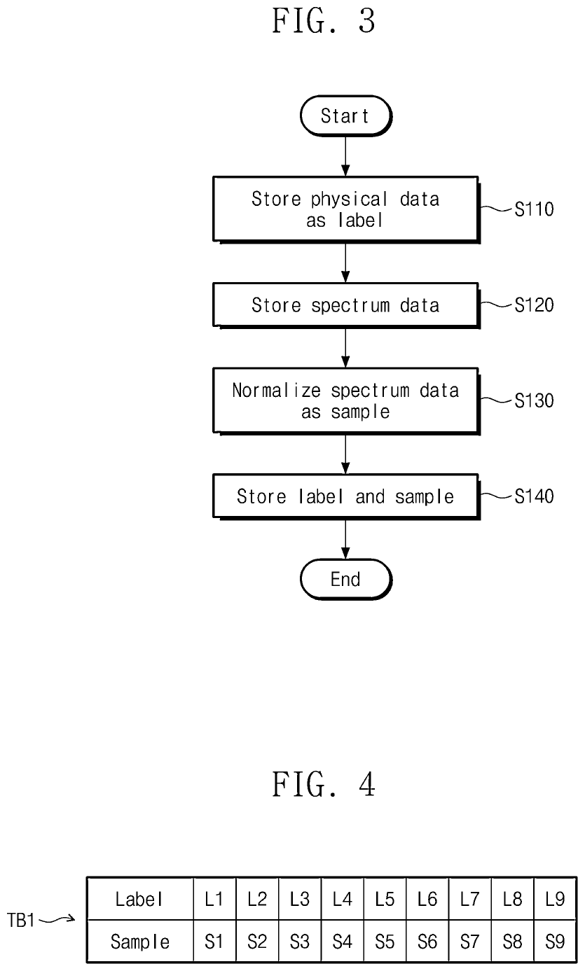

FIG. 3 illustrates an example of obtaining a sample-label pair for learning of a learning device according to one or more example embodiments of the present disclosure. The example of FIG. 3 may be applied for obtaining a sample-label pair for the learning of the learning module 17. Referring to FIGS. 1 and 3, in operation S110, the semiconductor manufacturing system 10 may store physical data as a label. For example, a processor (hereinafter, referred to as an internal processor or external processor of the database 15) which is placed inside or outside of the database 15 may measure physical data of an element(s) of a semiconductor device from image data (e.g., the first capture data CD1) captured from semiconductor devices formed in the wafer WAF by using the SEM and/or TEM.

The physical data related to a semiconductor device may include, for example but not limited to, a length of an element(s) of the semiconductor device, a distance between elements of the semiconductor device, and/or a thickness of an element(s) of the semiconductor device. The internal processor or external processor of the database 15 may store the physical data of the semiconductor device in the database 15 as a label.

In operation S120, the semiconductor manufacturing system 10 may store spectrum data. For example, the database 15 may store spectrum data (e.g., the second capture data CD2) measured from the semiconductor devices formed in the wafer WAF by using the ellipsometer.

In operation S130, the semiconductor manufacturing system 10 may normalize the spectrum data so as to be stored as a sample. For example, the internal processor or external process of the database 15 may normalize an intensity of a spectrum based on “0”. The internal processor or external process of the database 15 may select a specific spectrum as a reference spectrum and may normalize the spectrum data based on differences from the reference spectrum. The internal processor or external process of the database 15 may normalize the spectrum data by applying a linear relation equation to the spectrum data to move the spectrum.

In operation S140, the semiconductor manufacturing system 10 may store the label and the sample. For example, the database 15 may correlate a sample and a label which correspond to each other, so as to be stored as a sample-label pair.

In one or more example embodiments, the semiconductor manufacturing system 10 may store a plurality of (e.g., N, N being a positive integer) of sample-label pairs by repeatedly performing operation S110, operation S120, operation S130, and operation S140. The database 15 may provide the plurality of sample-label pairs to the learning module 17.

FIG. 4 illustrates an example of sample-label pairs stored in the database 15 according to one or more example embodiments of the present disclosure. Referring to FIGS. 1 and 4, in one or more example embodiments, sample-label pairs may be expressed in a form of a first table TB1. The sample-label pairs may include a first label L1 and a first sample S1 corresponding to the first label L1, a second label L2 and a second sample S2 corresponding to the second label L2, a third label L3 and a third sample S3 corresponding to the third label L3, a fourth label L4 and a fourth sample S4 corresponding to the fourth label L4, a fifth label L5 and a fifth sample S5 corresponding to the fifth label L5, a sixth label L6 and a sixth sample S6 corresponding to the sixth label L6, a seventh label L7 and a seventh sample S7 corresponding to the seventh label L7, an eighth label L8 and an eighth sample S8 corresponding to the eighth label L8, and a ninth label L9 and a ninth sample S9 corresponding to the ninth label L9.

For example, the first label L1, the second label L2, the third label L3, the fourth label L4, the fifth label L5, the sixth label L6, the seventh label L7, the eighth label L8, and the ninth label L9 may indicate physical values of a semiconductor device, such as a length of an element(s) of the semiconductor device, a distance between elements of the semiconductor device, and/or a thickness of an element(s) of the semiconductor device.

For brief description, in FIG. 4, it is assumed that numbers associated with the first label L1, the second label L2, the third label L3, the fourth label L4, the fifth label L5, the sixth label L6, the seventh label L7, the eighth label L8, and the ninth label L9 correspond to relevant values listed in ascending order from lowest to highest values. That is, as a number associated with a label increases, a physical value indicated by the label may become greater (or smaller).

Numbers associated with the first sample S1, the second sample S2, the third sample S3, the fourth sample S4, the fifth sample S5, the sixth sample S6, the seventh sample S7, the eighth sample S8, and the ninth sample S9 may not be associated with data (e.g., a spectrum) indicated by samples and may be used to distinguish different samples.

In one or more example embodiments, unless the assumption that numbers associated with labels are listed in ascending order from lowest to highest values is explicitly mentioned, it is assumed that the numbers associated with the labels are not associated with relevant values.

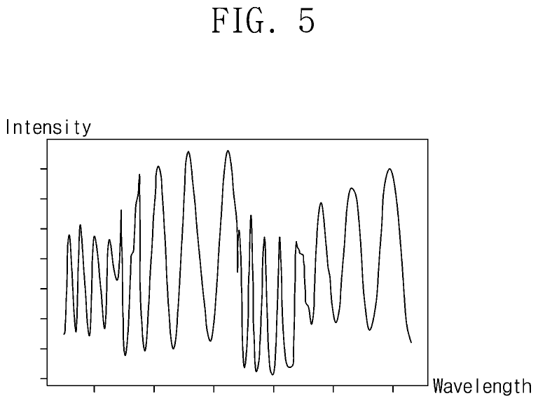

FIG. 5 is a diagram illustrating an example of a sample according to one or more example embodiments of the present disclosure. In FIG. 5, a spectrum measured from a semiconductor device by an ellipsometer may be obtained as a sample, and a horizontal axis represents a wavelength of the spectrum, and a vertical axis represents an intensity of the spectrum. Referring to FIGS. 1 and 5, the spectrum obtained from the semiconductor device by using the ellipsometer may appear at various intensities in wide wavelength ranges.

When a physical value of the semiconductor device such as a length of an element(s) of the semiconductor device, a distance between elements of the semiconductor device, or a thickness of an element(s) of the semiconductor device changes, the spectrum obtained from the semiconductor device by using the ellipsometer may change. That is, the spectrum obtained from the semiconductor device by using the ellipsometer may include information about the physical value of the semiconductor device such as a length of an element(s) of the semiconductor device, a distance between elements of the semiconductor device, or a thickness of an element(s) of the semiconductor device.

Sample-label pairs may be used for machine learning (or training) of the learning module 17 that may predict (or inferring) labels from samples. For example, the sample-label pairs may be used for regression analysis-based machine learning of the learning module 17.

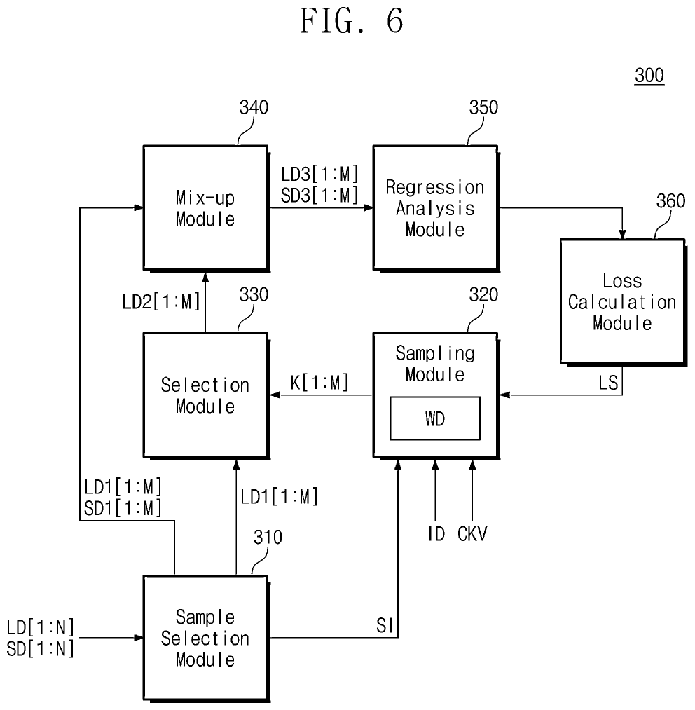

FIG. 6 illustrates an example of a learning module 300 according to an example embodiment of the present disclosure. In one or more example embodiments, the learning module 300 may correspond to the learning module 17 of FIG. 1. Referring to FIGS. 1 and 6, the learning module 300 may include a sample selection module 310, a sampling module 320, a selection module 330, a mix-up module 340, a regression analysis module 350, and a loss calculation module 360.

The sample selection module 310 may select some of sample-label pairs. For example, the sample selection module 310 may receive “N” sample-label pairs (N being a positive integer) from the database 15. The N sample-label pairs may include N labels LD [1: N] and N samples SD [1: N] respectively corresponding to the N labels LD [1: N].

The sample selection module 310 may select M sample-label pairs (M being a positive integer less than N) from the received N sample-label pairs. That is, the M sample-label pairs are some of the N sample-label pairs. The M sample-label pairs may include M first labels LD1 [1: M] and M first samples SD1 [1: M] respectively corresponding to the M first labels LD1 [1: M].

In one or more example embodiments, the sample selection module 310 may select M sample-label pairs according to a given algorithm or randomly. The sample selection module 310 may provide selection information SI including information about M values to the sampling module 320. The sample selection module 310 may provide the M first labels LD1 [1: M] to the selection module 330. The sample selection module 310 may provide the M first labels LD1 [1: M] and the M first samples SD1 [1: M] to the mix-up module 340.

In one or more example embodiments, the sample selection module 310 may be omitted. Alternatively, the sample selection module 310 may be configured to select all the N sample-label pairs.

The sampling module 320 may be implemented in a machine learning module. For example, the sampling module 320 may be implemented based on one of various neural networks such as a DNN (Deep Neural Network), a CNN (Convolution Neural Network), a RNN (Recurrent Neural Network), and an FFNN (FeedForward Neural Network).

The sampling module 320 may receive input data ID. The input data ID may include fixed data with a specific pattern. For example, the input data ID may be implemented to have various patterns such as a random data pattern, a pattern in which all data bits are “1”, and a pattern in which all data bits are “0”. The input data ID may be fixed from a point in time when the learning of the learning module 300 starts to a point in time when the learning of the learning module 300 ends. For example, the input data ID may be generated by the learning module 300 or may be received from an external module or an external device.

The sampling module 320 may receive candidate K-values CKV. The candidate K-values CKV may indicate candidate values which K-values can have. For example, the candidate K-values CKV may include various values including exponents of 4 such as 0, 1, 4, 16, 64, and 256 or exponents of 2 such as 0, 1, 2, 4, 8, 16, 32, and 64, etc.

The sampling module 320 may identify a number of K-values as M, based on the selection information SI from the sample selection module 310.

The sampling module 320 may include weight data WD. The sampling module 320 may include a machine learning module that is trained to infer M K-values K [1: M] from the input data ID by using the weight data WD. The M K-values K [1: M] may respectively correspond to the M first labels LD1 [1: M]. The sampling module 320 may infer each of the M K-values K [1: M] as one of values indicated by the candidate K-values CKV.

The selection module 330 may receive the M K-values K [1: M] from the sampling module 320. The selection module 330 may receive the M first labels LD1 [1: M] from the sample selection module 310. Based on a corresponding K-value among the M K-values K [1: M], the selection module 330 may select a label, which is targeted for the mix-up data augmentation with each of the M first labels LD1 [1: M], from the M first labels LD1 [1: M].

For example, each of the M K-values K [1: M] may include distance information. A specific K-value may include distance information associated with a corresponding first label. Based on a corresponding K-value, that is, the distance information, the selection module 330 may select a label, which is targeted for the mix-up data augmentation with each of the M first labels LD1 [1: M], from the M first labels LD1 [1: M].

For example, the selection module 330 may select clusters of first labels adjacent to a specific first label based on the K-value. Each cluster of first labels may include K labels (e.g., K number of first labels). The selection module 330 may select one cluster, based on distances between the specific first label and the clusters of the first labels. The selection module 330 may select one first label among the first labels in the selected cluster as a target for the mix-up data augmentation with the specific first label, based on distances between the specific first label and the first labels of the selected cluster.

The selection module 330 may output M second labels LD2 [1: M] to be respectively mixed up with the M first labels LD1 [1: M].

As another example, the selection module 330 may select a label, which is targeted for the mix-up data augmentation with each of the M first labels LD1 [1: M], from among the N labels LD [1: N]. For example, the selection module 330 may receive the N labels LD [1: N] from the sample selection module 310. The selection module 330 may further receive the N samples SD [1: N]. The selection module 330 may select the M second labels LD2 [1: M], to be respectively mixed up with the M first labels LD1 [1: M], from the received N labels LD [1: N], and provide the selected M second labels LD2 [1: M] to the mix-up module 340. The selection module 330 may further provide the mix-up module 340 with M second samples (not illustrated) respectively corresponding to the selected M second labels LD2 [1: M].

The mix-up module 340 may receive the M first labels LD1 [1: M] and the M first samples SD1 [1: M] from the sample selection module 310. The mix-up module 340 may receive the M second labels LD2 [1: M] from the selection module 330.

In one or more example embodiments, when the selection module 330 selects the M second labels LD2 [1: M] among the M first labels LD1 [1: M], each of the M second labels LD2 [1: M] may be one of the M first labels LD1 [1: M]. Based on a value of each of the M second labels LD2 [1: M], the selection module 330 may identify a sample corresponding to each of the M second labels LD2 [1: M] from among values of the M first samples SD1 [1: M]. Samples respectively corresponding to the M second labels LD2 [1: M] may be M second samples (not illustrated).

In one or more example embodiments, when the selection module 330 selects the M second labels LD2 [1: M] among the N labels LD [1: N], the mix-up module 340 may further receive M second samples (not illustrated) respectively corresponding to the M second labels LD2 [1: M] from the selection module 330. The M second labels LD2 [1: M] and the M second samples (not illustrated) may constitute M second sample-label pairs.

The mix-up module 340 may mix up the M first labels LD1 [1: M] and the M second labels LD2 [1: M] to generate M third labels LD3 [1: M]. For example, the mix-up module 340 may generate, as a third label, a median value, an average value, or a weighted average value of the value of the specific first label and the value of the corresponding second label; however, example embodiments are not limited thereto.

The mix-up module 340 may generate M third samples SD3 [1: M] respectively corresponding to the M third labels LD3 [1: M] by mixing up the M first samples SD1 [1: M], respectively corresponding to the M first labels LD1 [1: M], and the M second samples (not illustrated), respectively corresponding to the M second labels LD2 [1: M]. For example, the mix-up module 340 may generate, as a third sample, a median spectrum, an average spectrum, or a weighted average spectrum of a spectrum of the specific first sample and a spectrum of a corresponding second sample; however, example embodiments are not limited thereto.

The mix-up module 340 may generate M third sample-label pairs by performing the mix-up data augmentation with respect to M first sample-label pairs and M second sample-label pairs. The M third sample-label pairs may include the M third labels LD3 [1: M] and the M third samples SD3 [1: M].

The M third sample-label pairs may be new data not belonging to existing M (or N) sample-label pairs (that is, M first sample-label pairs, M second sample-label pairs and/or N sample-label pairs). The mix-up module 340 may generate data for machine learning, which do not require labeling, by generating new sample-label pairs for machine learning through the mix-up data augmentation. Also, the consistency of machine learning may be improved by selecting a target for the mix-up data augmentation based on distances of labels.

The regression analysis module 350 may receive the M third sample-label pairs including the M third labels LD3 [1: M] and the M third samples SD3 [1: M] from the mix-up module 340. The regression analysis module 350 may perform machine learning based on the M third sample-label pairs. For example, the regression analysis module 350 may predict (or infer) M labels from the M third samples SD3 [1: M].

The loss calculation module 360 may calculate a loss LS of the regression analysis module 350. For example, the loss calculation module 360 may calculate differences between the M labels predicted (or inferred) by the regression analysis module 350 and the M third labels LD3 [1: M], as the loss LS.

The sampling module 320 may update the weight data WD based on the loss LS. For example, the sampling module 320 may update the weight data WD such that the loss LS decreases. Although the weight data WD are updated, the input data ID may be fixed.

As described above, the learning module 300 may perform the mix-up data augmentation based on K-values. The learning module 300 may perform the learning (or training) of the regression analysis module 350 based on data generated by the mix-up data augmentation. The learning module 300 may perform the learning of the sampling module 320 that generates the K-values such that the loss LS of the regression analysis module 350 decreases.

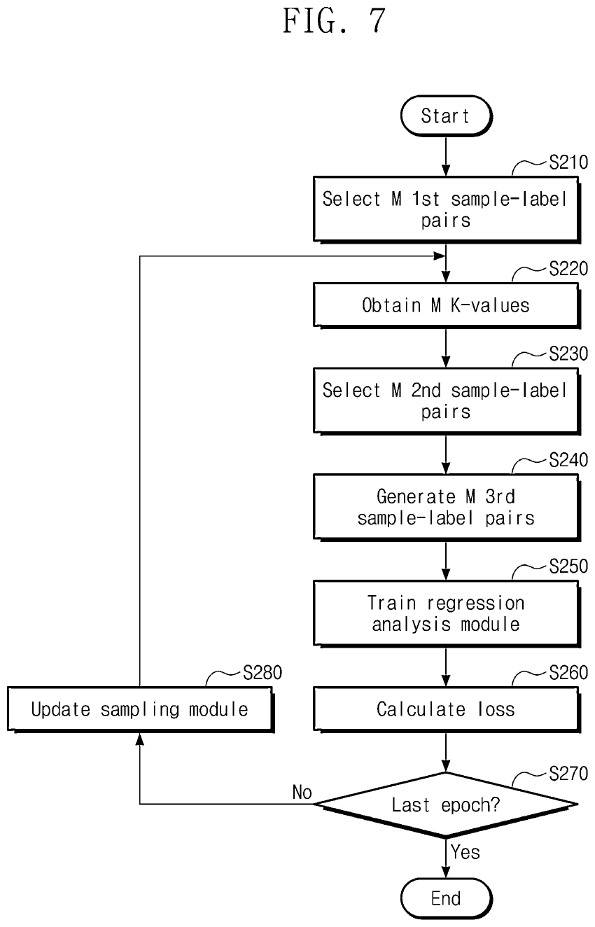

FIG. 7 illustrates a method of operating a learning module according to one or more example embodiments of the present disclosure. The method of FIG. 7 may apply to the learning module 300 of FIG. 6. Referring to FIGS. 1, 6, and 7, in operation S210, the learning module 300 may select M first sample-label pairs. For example, the sample selection module 310 may select M first sample-label pairs including the M first labels LD1 [1: M] and the M first samples SD1 [1: M], among N sample-label pairs including the N labels LD [1: N] and the N samples SD [1: N].

In operation S220, the learning module 300 may obtain the M K-values K [1: M]. For example, the sampling module 320 may obtain the M K-values K [1: M] by performing inference based on the input data ID and the weight data WD. Each of the MK-values K [1: M] may be one of values indicated by the candidate K-values CKV.

In operation S230, the learning module 300 may select M second sample-label pairs. For example, based on the M K-values K [1: M], the selection module 330 may select sample-label pairs, which include the M second labels LD2 [1: M] and the M second samples (not illustrated) targeted for the mix-up data augmentation, from among the M first sample-label pairs or the N sample-label pairs.

In operation S240, the learning module 300 may generate M third sample-label pairs. For example, the mix-up module 340 may generate the M third sample-label pairs including the M third labels LD3 [1: M] and the M third samples SD3 [1: M] by performing the mix-up data augmentation with respect to the M first sample-label pairs and the M second sample-label pairs. The mix-up module 340 may generate the M third labels LD3 [1: M] by performing the mix-up data augmentation with respect to the M first labels LD1 [1: M] and the M second labels LD2 [1: M]. The mix-up module 340 may generate the M third samples SD3 [1: M] by performing the mix-up data augmentation with respect to the first samples SD1 [1: M] and the M second samples (not illustrated).

In operation S250, the learning module 300 may train the regression analysis module 350. For example, the learning module 300 may perform the training (or learning) of the regression analysis module 350 such that the regression analysis module 350 predicts (or infers) M labels from the M third samples SD3 [1: M].

In operation S260, the learning module 300 may calculate the loss LS of the regression analysis module 450. For example, the loss calculation module 360 may calculate, as the loss LS, differences between the M labels predicted (or inferred) by the regression analysis module 350 and the M third labels LD3 [1: M].

In operation S270, the learning module 300 may determine whether a last epoch is performed. For example, operation S220, operation S230, operation S240, operation S250, and operation S260 may constitute one epoch. For example, when the loss LS converges into a value smaller than a threshold loss, the learning module 300 may determine that the last epoch is performed.

For example, the learning module 300 may have a maximum number of epochs and a threshold loss, which are determined based on a policy or by an external module or device. When an epoch in which the loss LS is smaller than the threshold loss is repeated as many times as the maximum number of epochs, the learning module 300 may determine that the last epoch is performed. As another example, when epochs are performed as many times as the maximum number of epochs and the loss LS is smaller than the threshold loss, the learning module 300 may determine that the last epoch is performed. However, these are merely examples and example embodiments are not limited thereto.

When the last epoch is performed, the learning module 300 may terminate the learning. For example, the learning module 300 may terminate the learning of the regression analysis module 350 and the sampling module 320, which is performed based on the M first sample-label pairs including the first labels LD1 [1: M] and the first samples SD1 [1: M] and the mix-up data augmentation. Afterwards, the learning module 300 may perform learning based on M other sample-label pairs. Alternatively, the regression analysis module 350 whose learning is performed by the learning module 300 may be used to predict (or infer) labels from new samples.

When the last epoch is not performed, in operation S280, the learning module 300 may update the sampling module 320. For example, the sampling module 320 may update the weight data WD based on the loss LS. For example, the sampling module 320 may update the weight data WD such that the loss LS decreases. Afterwards, in operation S220, the learning module 300 may select new K-values and may start a new epoch.

In one or more example embodiments, the learning module 300 may be implemented such that the learning ends, regardless of whether the threshold loss or less is achieved, after an epoch is repeated as many times as the maximum number of epochs. In the above configuration, the learning module 300 may first determine whether the last epoch is performed before the calculation of the loss LS. When the last epoch is performed, the learning module 300 may terminate the learning without calculating the loss LS. When the last epoch is not performed, the learning module 300 may calculate the loss LS and may update the sampling module 320.

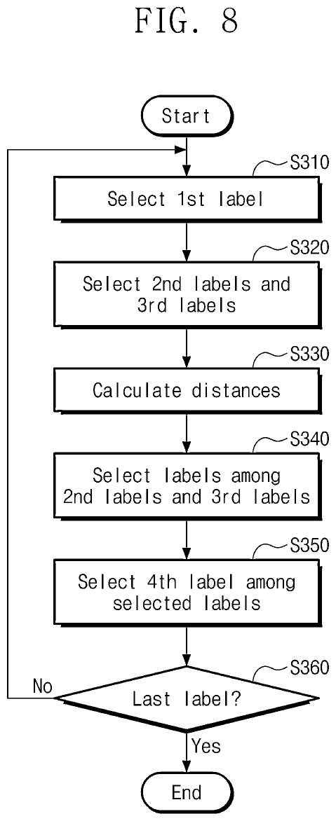

FIG. 8 illustrates a method in which a learning module according to one or more example embodiments of the present disclosure performs mix-up data augmentation. The method of FIG. 8 may apply to the learning module 300 of FIG. 6. Referring to FIGS. 1, 6, and 8, in operation S310, the learning module 300 may select a first label. For example, the selection module 330 may select a first mix-up target, on which the mix-up data augmentation is to be performed, as a first label. The selection module 330 may select one of the M first labels LD1 [1: M] being original data as the first label.

In operation S320, the learning module 300 may select second labels and third labels. For example, to select a second mix-up target on which the mix-up data augmentation is to be performed, the selection module 330 may select the second labels (e.g., a first cluster) and the third labels (e.g., a second cluster).

The selection module 330 may select labels, which have a value smaller than a value of the first label and closest to the value of the first label, and a number of which corresponds to a K-value, from among the M first labels LD1 [1: M] or the N labels LD [1: N], as the second labels.

The selection module 330 may select labels, which have a value greater than the value of the first label and closest to the value of the first label, and a number of which corresponds to the K-value, from among the M first labels LD1 [1: M] or the N labels LD [1: N], as the third labels.

In operation S330, the learning module 300 may calculate distances. For example, the selection module 330 may calculate a distance between the first label and the first cluster. The distance between the first label and the first cluster may be a sum of distances between the first label and the second labels included in the first cluster.

The selection module 330 may calculate a distance between the first label and the second cluster. The distance between the first label and the second cluster may be a sum of distances between the first label and the third labels included in the second cluster.

In operation S340, the learning module 300 may select labels among the second labels and the third labels. For example, the selection module 330 may select one of the first cluster and the second cluster based on the calculated distances. The selection module 330 may select labels of a cluster closer to the first label, among the first cluster and the second cluster.

In operation S350, the learning module 300 may select fourth labels among the selected labels. For example, the selection module 330 may select a label having a value closest to the value of the first label from among labels of a cluster selected from the first cluster and the second cluster, as the fourth label. The fourth label may be the second mix-up target on which the mix-up data augmentation is to be performed. The fourth label may be included as one of the M second labels LD2 [1: M] and may be a target of the mix-up data augmentation together with the first label among the M first labels LD1 [1: M]. That is, the mix-up data augmentation may be performed on the first label and the fourth label.

In operation S360, the learning module 300 may determine that a currently selected label corresponds to a last label among the M first labels LD1 [1: M]. For example, the selection module 330 may determine whether all the M second labels LD2 [1: M] respectively corresponding to the M first labels LD1 [1: M] are selected as a target of the mix-up data augmentation. When a label selected as a target of the mix-up data augmentation (e.g., the first mix-up target in S310) is the last label among the M first labels LD1 [1: M], the selection module 330 may terminate the selection and may output the M second labels LD2 [1: M]. When the label selected as a target of the mix-up data augmentation is not the last label among the M first labels LD1 [1: M], in operation S310, the selection module 330 may select a next label among the M first labels LD1 [1: M] as the first label (e.g., as the first mix-up target).

For example, the selection module 330 may be regarded as selecting target labels of the mix-up data augmentation based on the K-NN (K-Nearest Neighbor) algorithm.

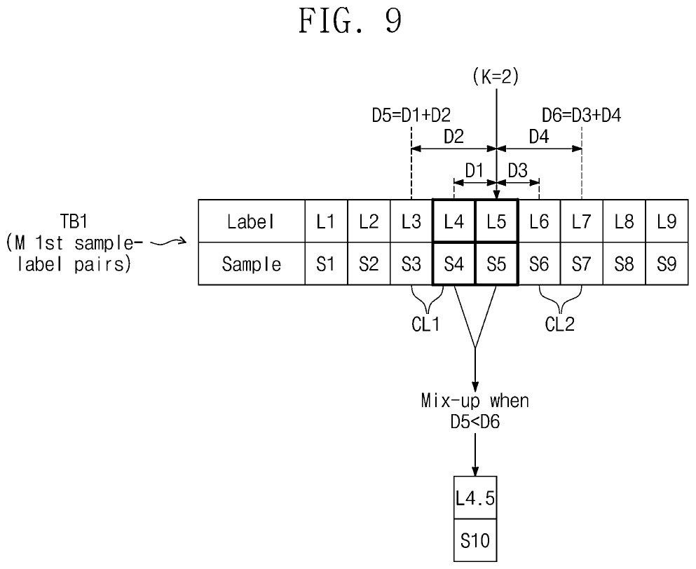

FIG. 9 illustrates an example of a process in which a learning module selects target labels of the mix-up data augmentation according to one or more example embodiments of the present disclosure. The process of FIG. 9 may apply to the learning module 300 of FIG. 6.

For brief description, in FIG. 9, it is assumed that values associated with the first label L1, the second label L2, the third label L3, the fourth label L4, the fifth label L5, the sixth label L6, the seventh label L7, the eighth label L8, and the ninth label L9 are in an ascending order as listed from lowest to highest values or in a descending order as listed from highest to lowest values. That is, as a number denoting each label increases, a value (e.g., physical value) indicated by the label may become greater (or smaller).

Numbers denoting the first sample S1, the second sample S2, the third sample S3, the fourth sample S4, the fifth sample S5, the sixth sample S6, the seventh sample S7, the eighth sample S8, and the ninth sample S9 may be used to distinguish samples from each other and may not be associated with data (e.g., a spectrum) indicated by samples.

In one or more example embodiments, if it is not explicitly mentioned that numbers denoting labels are listed in an ascending order from lowest to highest values, it is assumed that the numbers denoting the labels are not associated with relevant values indicated by the labels.

Referring to FIGS. 1, 6, 8, and 9, the selection module 330 of the learning module 300 may select target labels of the mix-up data augmentation from the M first sample-label pairs of the first table TB1. In one or more example embodiments, it is assumed that a K-value corresponding to the fifth label L5 is 2 (K=2).

In one or more example embodiments, the selection module 330 may select the fifth label L5 among labels of the M first sample-label pairs as a first mix-up target (e.g., the first label in operation S310 of FIG. 8) for the mix-up data augmentation.

The selection module 330 may select the third label L3 and the fourth label L4, which have values that are smaller than a value of the fifth label L5, which have values that are closest to the value of the fifth label L5, the number of which corresponds to the K-value (e.g., 2), as the second labels in operation S320 of FIG. 8 (e.g., as second labels of a first cluster CL1).

The selection module 330 may select the sixth label L6 and the seventh label L7, which have values that are greater than the value of the fifth label L5, which have values that are closest to the value of the fifth label L5, and the number of which corresponds to a K-value (e.g., 2), as the third labels in operation S320 of FIG. 8 (e.g., as third labels of a second cluster CL2).

The selection module 330 may calculate a first distance D1 between the fourth label L4 of the first cluster CL1 and the fifth label L5 and a second distance D2 between the third label L3 of the first cluster CL1 and the fifth label L5. The selection module 330 may calculate a third distance D3 between the sixth label L6 of the second cluster CL2 and the fifth label L5 and a fourth distance D4 between the seventh label L7 of the second cluster CL2 and the fifth label L5.

For example, the selection module 330 may calculate a fifth distance D5 between the first cluster CL1 including the third label L3 and the fourth label L4 and the fifth label L5 as a sum of the first distance D1 and the second distance D2. For example, the selection module 330 may calculate a sixth distance D6 between the second cluster CL2 including the sixth label L6 and the seventh label L7 and the fifth label L5 as a sum of the third distance D3 and the fourth distance D4.

In one or more example embodiments, the fifth distance D5 may be smaller than the sixth distance D6. That is, the distance between the first cluster CL1 and the fifth label L5 may be smaller than the distance between the second cluster CL2 and the fifth label L5 (or the first cluster CL1 may be closer to the fifth label L5 than the second cluster CL2). The selection module 330 may select the third label L3 and the fourth label L4 of the first cluster CL1.

The selection module 330 may select a label being closer to the fifth label L5 from among the third label L3 and the fourth label L4 of the first cluster CL1 as the second mix-up target of the mix-up data augmentation. For example, the selection module 330 may select the fourth label L4 as the second mix-up target of the mix-up data augmentation.

The mix-up module 340 may mix up a value of the fourth label L4 and a value of the fifth label L5 to generate a new label. For example, the new label may correspond to a median value of the value of the fourth label L4 and the value of the fifth label L5 and may be denoted as, for example, a 4.5-th label L4.5.

The mix-up module 340 may mix up the fourth sample S4 corresponding to the fourth label L4 and the fifth sample S5 corresponding to the fifth label L5 to generate a new sample. For example, the new sample may be denoted as a tenth sample S10.

The 4.5-th label L4.5 may be one of the M third labels LD3 [1: M]. The tenth sample S10 may be one of the M first samples SD1 [1: M]. A sample-label pair including the 4.5-th label L4.5 and the tenth sample S10 may be one of the M third sample-label pairs.

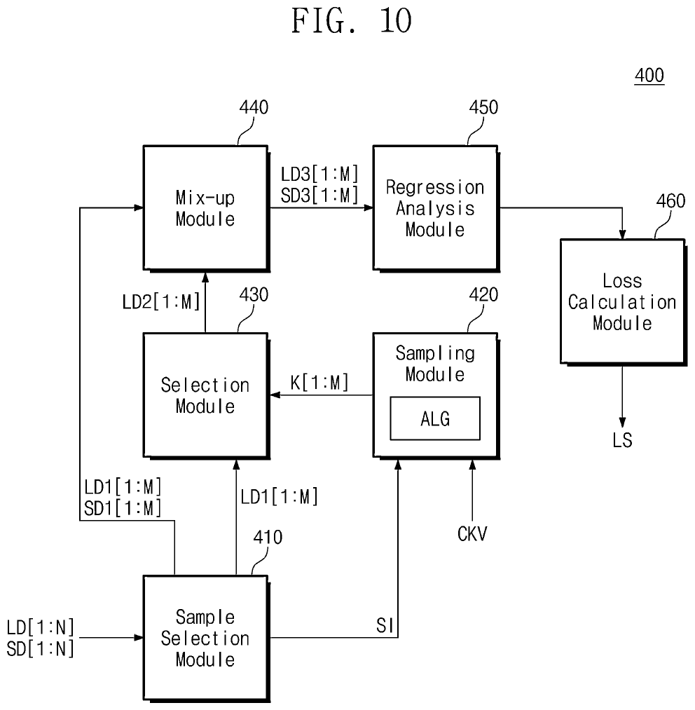

FIG. 10 illustrates another example of a learning module 400 according to one or more example embodiments of the present disclosure. In one or more example embodiments, the learning module 400 may correspond to the learning module 17 of FIG. 1. Referring to FIGS. 1 and 10, the learning module 400 may include a sample selection module 410, a sampling module 420, a selection module 430, a mix-up module 440, a regression analysis module 450, and a loss calculation module 460.

Configurations and operations of the sample selection module 410, the selection module 430, the mix-up module 440, and the regression analysis module 450 may be the same as or similar to those of the sample selection module 310, the selection module 330, the mix-up module 340, and the regression analysis module 350. Thus, additional description will be omitted to avoid redundancy.

Compared to the learning module 300 of FIG. 6, the learning module 400 may include the loss calculation module 460, but the loss LS calculated by the loss calculation module 460 may not be applied to the sampling module 420. That is, the learning module 400 may not update the sampling module 420 based on the loss LS of the regression analysis module 450. The loss LS may be used to determine whether the regression analysis module 450 converges.

The sampling module 420 may include an algorithm ALG instead of the weight data WD, and an operation of the sampling module 420 may be similar to that of the sampling module 320 of FIG. 6 except that the sampling module 420 does not receive the input data ID and the loss LS. For example, the sampling module 420 may receive the selection information SI from the sample selection module 410 and may receive the candidate K-values CKV.

The sampling module 420 may repeatedly perform an operation of selecting one of the candidate K-values CKV based on the algorithm ALG, as many times as a value indicated by the selection information SI. For example, the algorithm ALG may include a random selection algorithm.

The learning module 400 may select K-values including information about a distance used at the time of selecting mix-up targets of the mix-up data augmentation, based on an algorithm and may perform the learning (or training) of the regression analysis module 450.

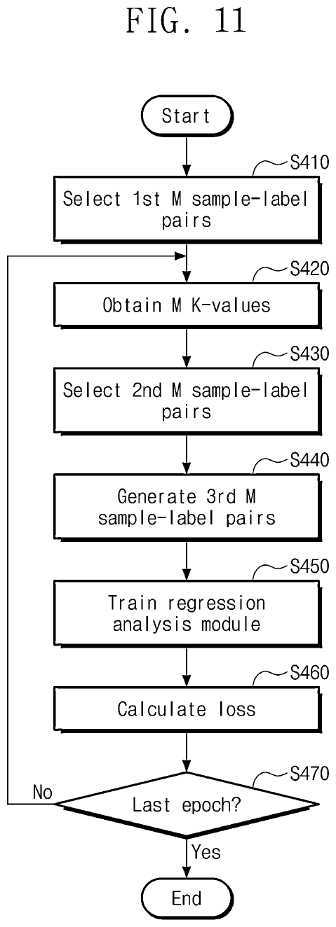

FIG. 11 illustrates a method of operating the learning module 400 according to one or more example embodiments of the present disclosure. Referring to FIGS. 1, 10, and 11, in operation S410, the learning module 400 may select M first sample-label pairs. Operation S410 may be the same as or similar to operation S210. Thus, additional description will be omitted to avoid redundancy.

In operation S420, the learning module 400 may obtain the M K-values K [1: M]. For example, the sampling module 420 may repeatedly perform an operation of selecting one of the candidate K-values CKV based on the algorithm ALG, as many times as a value indicated by the selection information SI.

In operation S430, the learning module 400 may select M second sample-label pairs. Operation S430 may be the same as or similar to operation S230. Thus, additional description will be omitted to avoid redundancy.

In operation S440, the learning module 400 may generate M third sample-label pairs. Operation S440 may be the same as or similar to operation S240. Thus, additional description will be omitted to avoid redundancy.

In operation S450, the learning module 400 may train the regression analysis module 450. Operation S450 may be the same as or similar to operation S250. Thus, additional description will be omitted to avoid redundancy.

In operation S460, the learning module 300 may calculate the loss LS. Operation S460 may be the same as or similar to operation S260. Thus, additional description will be omitted to avoid redundancy.

In operation S460, the learning module 400 may determine whether a last epoch is performed. For example, operation S420, operation S430, operation S440, and operation S450 may constitute one epoch. For example, when the loss LS converges into a value smaller than a threshold loss, the learning module 400 may determine that the last epoch is performed.

For example, the learning module 400 may have a maximum number of epochs and a threshold loss, which are determined based on a policy or by an external module or device. When an epoch in which the loss LS is smaller than the threshold loss is repeated as many times as the maximum number of epochs, the learning module 400 may determine that the last epoch is performed. As another example, when epochs are performed as many times as the maximum number of epochs and the loss LS is smaller than the threshold loss, the learning module 400 may determine that the last epoch is performed. However, these are merely examples and example embodiments are not limited thereto.

When the last epoch is performed, the learning module 400 may terminate the learning. For example, the learning module 400 may terminate the learning of the regression analysis module 450 and the sampling module 420, which is performed based on the M first sample-label pairs including the first labels LD1 [1: M] and the first samples SD1 [1: M] and the mix-up data augmentation. Afterwards, the learning module 400 may perform learning based on M other sample-label pairs. Alternatively, the regression analysis module 450 whose learning is performed by the learning module 400 may be used to predict (or infer) labels from new samples.

When the last epoch is not performed, in operation S420, the learning module 400 may select new K-values and may start a new epoch.

In one or more example embodiments, the learning module 400 may be implemented such that the learning ends, regardless of the threshold loss or less is achieved, after an epoch is repeated as many times as the maximum number of epochs. In the above configuration, the learning module 400 may not calculate the loss LS. The learning module 400 may not include the loss calculation module 460.

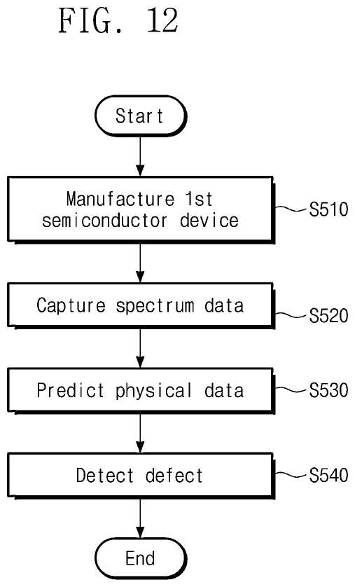

FIG. 12 illustrates an example in which a learning device (e.g., the learning module 17) is applied to the manufacture of semiconductor devices after the learning of the learning device is completed, according to one or more example embodiments of the present disclosure. In one or more example embodiments, after the learning of the regression analysis module 350 or 450 is completed, the learning module 17 may include the learning module 300 or 400 or to only include the regression analysis module 350 or 450.

Referring to FIGS. 1, 6, 10, and 12, in operation S510, the semiconductor manufacturing system 10 may manufacture a first semiconductor device. For example, the semiconductor manufacturing system 10 may manufacture semiconductor devices including the first semiconductor device on the wafer WAF by applying processes PRS to the wafer WAF as described with reference to FIG. 1.

In operation S520, the semiconductor manufacturing system 10 may capture a spectrum of the first semiconductor device. For example, the semiconductor manufacturing system 10 may capture spectrum data of semiconductor devices, for example, the first semiconductor device as the second capture data CD2 by using the ellipsometer of the capturing device 14.

In operation S530, the semiconductor manufacturing system 10 may predict physical data. For example, the learning module 17 may be trained to predict (or infer) a physical characteristic, as a label, from spectrum data that is input as a sample, and therefore, the learning module 17 may predict (or infer) physical data from the spectrum data.

In operation S540, the semiconductor manufacturing system 10 may detect a defect. For example, the physical data predicted (or inferred) by the learning module 17 may include a length of an element(s) of a semiconductor device, a distance between elements of a semiconductor device, and/or a thickness of an element(s) of a semiconductor device. When the length of the element(s) of the first semiconductor device, the distance between the elements of the first semiconductor device, or the thickness of the element(s) of the first semiconductor device is greater than or smaller than a corresponding threshold value, the semiconductor manufacturing system 10 may determine that the first semiconductor device is defective (or is free from a defect).

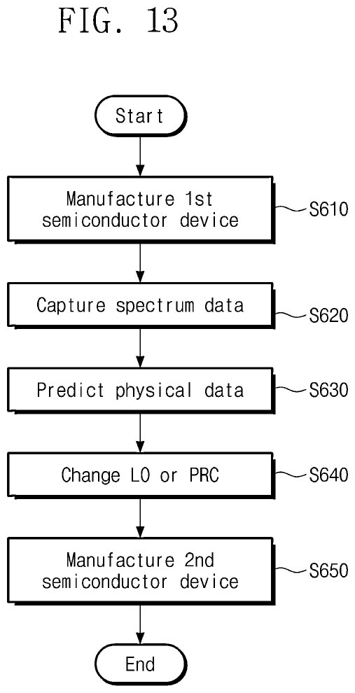

FIG. 13 illustrates another example in which a learning device (e.g., the learning module 17) is applied to the manufacture of semiconductor devices after the learning of the learning device is completed, according to one or more example embodiments of the present disclosure. In one or more example embodiments, after the learning of the regression analysis module 350 or 450 is completed, the learning module 17 may be changed to include the learning module 300 or 400 or to only include the regression analysis module 350 or 450.

Referring to FIGS. 1, 6, 10, and 13, in operation S610, the semiconductor manufacturing system 10 may manufacture a first semiconductor device. For example, the semiconductor manufacturing system 10 may manufacture semiconductor devices including the first semiconductor device on the wafer WAF by applying the processes PRS to the wafer WAF as described with reference to FIG. 1.

In operation S620, the semiconductor manufacturing system 10 may capture a spectrum of the first semiconductor device. For example, the semiconductor manufacturing system 10 may capture spectrum data of semiconductor devices, for example, the first semiconductor device as the second capture data CD2 by using the ellipsometer of the capturing device 14.

In operation S630, the semiconductor manufacturing system 10 may predict physical data. For example, because the learning module 17 is trained to predict (or infer) a physical characteristic, as a label, from spectrum data that is input as a sample, the learning module 17 may predict (or infer) physical data from the spectrum data.

In operation S640, the semiconductor manufacturing system 10 may change the layout image LO or the processes PRS. For example, the physical data predicted (or inferred) by the learning module 17 may include a length of an element(s) of a semiconductor device, a distance between elements a semiconductor device, and/or a thickness of an element(s) a semiconductor device. When the length of the element(s) of the first semiconductor device, the distance between the elements of the first semiconductor device, or the thickness of the element(s) of the first semiconductor device is greater than or smaller than a corresponding threshold value, the semiconductor manufacturing system 10 may determine that the layout image LO or the processes PRS to be applied to the first semiconductor device is not appropriate.

The semiconductor manufacturing system 10 may increase or decrease a size of an element(s) whose corresponding value(s) is greater than or smaller than the corresponding threshold value. Alternatively, the semiconductor manufacturing system 10 may decrease or increase an amount of a material, a temperature, and/or a time taken to apply a process to the element(s) whose value(s) is greater than or smaller than the corresponding threshold value.

Labels obtained from the semiconductor devices may have consecutive values. Samples may include features corresponding to the labels. When a distance between labels increases, features appearing at the samples may also change. According to one or more example embodiments of the present disclosure, a distance between labels which are used in the mix-up data augmentation may be limited based on K-values. As distances between labels whose values are consecutive are limited in the mix-up data augmentation, features of samples corresponding to labels distant from each other (and thus may not be associated with a mixed-up label) may be prevented from appearing at a sample corresponding the mixed-up label.

According to one or more example embodiments of the present disclosure, K-values which are used to limit a distance between labels may be inferred based on machine learning. Accordingly, K-values to be applied to the mix-up data augmentation may be optimized, and the performance of prediction of the regression analysis module 350 or 450 may be further improved.

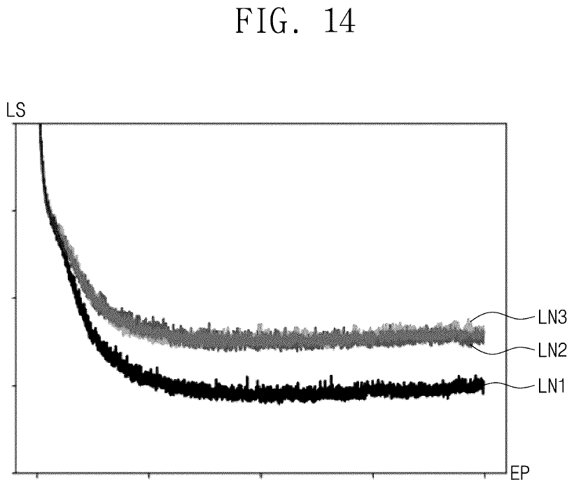

FIG. 14 illustrates a learning performance of the learning module 300 or 500 according to one or more example embodiments of the present disclosure and a learning performance of a comparative example in which a learning module according to one or more example embodiments of the present disclosure is not applied. In FIG. 14, a horizontal axis represents epochs EP, and a vertical axis represents the loss LS.

A first line LN1 shows a learning process of the learning module 17 according to one or more example embodiments of the present disclosure. A second line LN2 shows a learning process in which the training (or learning) of a learning module is performed based on all sample-label pairs without considering a distance between labels. A third line LN3 shows a learning process in which the training (or learning) of a learning module is performed based on sample-label pairs randomly sampled from all sample-label pairs without considering a distance between labels.

The learning results corresponding to the second line LN2 and the third line LN3 appear to converge to similar epochs EP with similar losses LS. According to one or more example embodiments of the present disclosure, the first line LN1 representing the learning process of the learning module 17, to which K-values each indicating a distance associated with a label are applied, appears to converge to a lower loss LS at a faster epoch EP compared to the second line LN2 and the third line LN3.

According to one or more example embodiments of the present disclosure, when the regression analysis and the mix-up data augmentation are applied to sample-label pairs having labels which are not discretely distinct but are consecutively distinct, the mix-up data augmentation may be performed based on K-values each indicating a distance associated with a label. According to one or more example embodiments of the present disclosure, the mix-up data augmentation may be applied to adjacent sample-label pairs, to which regression analysis may be applied. Accordingly, unsuitable mix-up data may be prevented from being applied to mix-up data augmentation, and thus, a label augmented based on the unsuitable mix-up data may be thereby prevented. Accordingly, a regression analysis module may be trained faster and more accurately by using fewer sample-label pairs.

According to one or more example embodiments of the present disclosure, a sample and a label may be generated based on the mix-up data augmentation. Accordingly, high consistency may be implemented by using a smaller number of samples and labels (or a smaller number of sample-label pairs). Also, according to one or more example embodiments of the present disclosure, the mix-up data augmentation may be performed based on a K-value indicating a distance. Accordingly, an electronic device that supports manufacturing of a semiconductor device while having improved consistency and an operating method of the electronic device are provided.

While the present disclosure has been described with reference to example embodiments thereof, it will be apparent to those of ordinary skill in the art that various changes and modifications may be made thereto without departing from the spirit and scope of the present disclosure as set forth in the following claims and their equivalents.

What is claimed is:

1. A method of operating an electronic device which includes at least one processor, the method comprising:
selecting, by the at least one processor, M (M being a positive integer) number of first sample-label pairs;
obtaining, by the at least one processor, M number of K-values;
selecting, by the at least one processor, M number of second sample-label pairs, respectively corresponding to the M number of first sample-label pairs, based on the M number of K-values;
generating, by the at least one processor, M number of third sample-label pairs based on the M number of first sample-label pairs and the M number of second sample-label pairs; and
training, by the at least one processor, a regression analysis module based on the M number of third sample-label pairs,
wherein each of the M number of first sample-label pairs, the M number of second sample-label pairs, and the M number of third sample-label pairs includes data measured from a semiconductor device as a sample and a label associated with the semiconductor device, and
wherein the regression analysis module is trained to predict labels, which are associated with the semiconductor device, from the M number of third sample-label pairs.

2. The method of claim 1, wherein samples of the M number of first sample-label pairs include spectrums obtained from the semiconductor device by using an ellipsometer, and
wherein labels of the M number of first sample-label pairs include physical values of the semiconductor device obtained by using at least one of a scanning electron microscope (SEM) or a transmission electron microscope (TEM).

3. The method of claim 1, further comprising:
receiving, by the at least one processor, N (N being a positive integer greater than M) sample-label pairs,
wherein the selecting the M number of first sample-label pairs includes:
randomly selecting the M number of first sample-label pairs among the N number of sample-label pairs.

4. The method of claim 1, wherein the obtaining the M number of K-values includes:
inferring, at a sampling module that is based on a machine learning, the M number of K-values from input data by using weight data.

5. The method of claim 4, wherein each of the M number of K-values is inferred as one of candidate K-values.

6. The method of claim 4, further comprising:
calculating a loss of the regression analysis module, which is associated with each of the M number of third sample-label pairs; and
updating the weight data of the sampling module such that the loss decreases.

7. The method of claim 4, wherein the input data include fixed values.

8. The method of claim 1, wherein the obtaining the M number of K-values includes:
obtaining each of the M number of K-values among candidate K-values based on a selection algorithm.

9. The method of claim 8, wherein the selection algorithm includes a random selection algorithm.

10. The method of claim 1, wherein the selecting the M number of second sample-label pairs includes:
selecting a first label having a first K-value from among labels of the M number of first sample-label pairs;
calculating first distances between the first label and second labels, a number of the second labels corresponding to the first K-value, from among the labels of the M number of first sample-label pairs;
calculating second distances between the first label and third labels, a number of the third labels corresponding to the first K-value, from among the labels of the M number of first sample-label pairs;
selecting, as fourth labels, either the second labels or the third labels, based on the first distances and the second distances; and
selecting a label that is closest to the first label, from among the fourth labels, as a label corresponding to the first label from among the labels of the M number of second sample-label pairs.

11. The method of claim 10, wherein the second labels have values, which are greater than a value of the first label and closer to the value of the first label, from among values of the labels of the M number of first sample-label pairs, and wherein the third labels have values, which are smaller than the value of the first label and are closer to the value of the first label, from among the values of the labels of the M number of first sample-label pairs.

12. The method of claim 1, wherein the selecting the M number of first sample-label pairs includes:
randomly selecting the M number of first sample-label pairs among N (N is a positive integer greater than M) sample-label pairs,
wherein the selecting the M number of second sample-label pairs includes:
selecting a first label having a first K-value from among labels of the M number of first sample-label pairs;
calculating first distances between the first label and second labels, a number of the second labels corresponding to the first K-value, from among labels of the N number of sample-label pairs;
calculating second distances between the first label and third labels, a number of the third labels corresponding to the first K-value, from among the labels of the N number of sample-label pairs;
selecting, as fourth labels, either the second labels or the third labels based on the first distances and the second distances; and
selecting a label that is closest to the first label from among the fourth labels, as a label corresponding to the first label from among labels of the M number of second sample-label pairs.

13. The method of claim 1, wherein the generating the M number of third sample-label pairs includes:
generating the M number of third sample-label pairs by performing mix-up data augmentation with respect to the M number of first sample-label pairs and the M number of second sample-label pairs.

14. An operating method of an electronic device which includes at least one processor, the method comprising:
receiving, by the at least one processor, a sample measured from a semiconductor device; and
predicting from the sample, by the at least one processor, a label associated with the semiconductor device by using a regression analysis module that is based on a machine learning,
wherein learning of the regression analysis module is performed based on mix-up data augmentation,
wherein the mix-up data augmentation includes:
selecting second sample-label pairs from first sample-label pairs based on K-values; and
generating third sample-label pairs by mixing up the first sample-label pairs and the second sample-label pairs, and
wherein the K-values include distance information corresponding to each of labels of the first sample-label pairs.

15. The method of claim 14, wherein the sample includes a spectrum obtained from the semiconductor device by using an ellipsometer, and
wherein the label includes physical information of the semiconductor device.

16. The method of claim 15, wherein the physical information includes at least one of a length of an element of the semiconductor device, a distance between elements of the semiconductor device, or a thickness of an element of the semiconductor device.

17. The method of claim 14, further comprising:
detecting a defect of the semiconductor device based on the predicted label.

18. The method of claim 14, further comprising:
changing a layout image or a process of the semiconductor device based on the predicted label.

19. The method of claim 14, wherein the K-values are obtained based on a machine learning module that is trained to infer the K-values from fixed input data by using weight data, and
wherein the weight data of the machine learning module are updated based on a loss of the third sample-label pairs.

20. An electronic device for predicting a characteristic of a semiconductor device, the electronic device comprising:
at least one processor; and
at least one memory configured to store M (M being a positive integer) number of first sample-label pairs,
wherein the at least one processor is configured to:
obtain M number of K-values;
select M number of second sample-label pairs, respectively corresponding to the number of M first sample-label pairs, based on the M number of K-values;
generate M number of third sample-label pairs based on the M number of first sample-label pairs and the M number of second sample-label pairs; and
train a regression analysis module based on the M number of third sample-label pairs,
wherein the regression analysis module is trained to predict labels, which are associated with the semiconductor device, from the M number of third sample-label pairs, and
wherein the K-values include distance information corresponding to each of labels of the first sample-label pairs.
